(19) United States
(12) Patent Application Publication
(10) Pub. No.: US 2015/0067444 A1
(43) Pub. Date: Mar. 5, 2015

(54) SEMICONDUCTOR STORAGE DEVICE AND MEMORY SYSTEM

(71) Applicant: KABUSHIKI KAISHA TOSHIBA, Tokyo (JP)

(72) Inventors: Yasuyuki EGUCHI, Kawasaki-Shi (JP); Jin KASHIWAGI, Tokyo (JP)

(21) Appl. No.: 14/203,473

(22) Filed: Mar. 10, 2014

Related U.S. Application Data
(60) Provisional application No. 61/873,797, filed on Sep. 4, 2013.

(51) Int. Cl. G06F 11/10; H03M 13/05

(52) U.S. Cl. CPC G06F 11/10; H03M 13/05
USPC 714/766

(57) ABSTRACT

A semiconductor storage device according to the present embodiment comprises a memory cell array including a plurality of memory cells. An output part is configured to output data based on a strobe signal. An error correction part is configured to correct an error in first data read from the memory cell array. The output part fixes level of the strobe signal when outputting the first data, if the number of error bits of the first data exceeds a first number, he error correction part being capable of correcting error of the first number in the first data.

### CROSS REFERENCE TO RELATED APPLICATIONS

This application is based upon and claims the benefit of priority from the prior U.S. Provisional Patent Application No. 61/873,797, filed on Sep. 4, 2013, the entire contents of which are incorporated herein by reference.

### FIELD

The embodiments of the present invention relate to a semiconductor storage device and memory system.

### BACKGROUND

As large-capacity non-volatile memory, MRAM (Magnetic Random Access Memory) has been widely known.

### BRIEF DESCRIPTION OF THE DRAWINGS

FIG. 1 is a block diagram showing an example of a configuration of an MRAM chip according to a first embodiment;

FIG. 2 is an explanatory diagram showing an example of a configuration of the single memory cell MC;

FIG. 3 is a schematic diagram showing an example of a memory system constituted by the MRAM chip and a host controller HOST according to the first embodiment;

FIG. 4 is a flowchart showing an example of the data read operation performed by the MRAM chip and the host controller HOST according to the first embodiment;

FIG. 5 is a timing chart showing an example of operations of the enable signal EN, the data strobe DQS, and the read data DQ;

FIG. 6 is a timing chart showing an example of operations of the enable signal EN, the data strobe DQS, and the read data DQ according to a modification of the first embodiment;

FIG. 7 is a schematic diagram showing an example of a memory system constituted by an MRAM chip and a host controller according to a second embodiment;

FIG. 8 is a flowchart showing an example of the data read operation performed by the MRAM chip and the host controller HOST according to the second embodiment; and

FIG. 9 is a timing chart showing an example of operations of the enable signal EN, the data strobe DQS, and the read data DQ according to a third embodiment.

### DETAILED DESCRIPTION

Embodiments will now be explained with reference to the accompanying drawings. The present invention is not limited to the embodiments.

A semiconductor storage device according to the present embodiment comprises a memory cell array including a plurality of memory cells. An output part is configured to output data based on a strobe signal. An error correction part is configured to correct an error in first data read from the memory cell array. The output part fixes level of the strobe signal when outputting the first data, if the number of error bits of the first data exceeds a first number, he error correction part being capable of correcting error of the first number in the first data.

Components with substantially the same functionalities and configurations will be referred to with the same reference number and duplicate descriptions will be made only when required.

While an MRAM is described as a semiconductor storage device in each of the following embodiments, the embodiments are also applicable to other nonvolatile memories (a NAND or an FeRAM, for example).

### First Embodiment

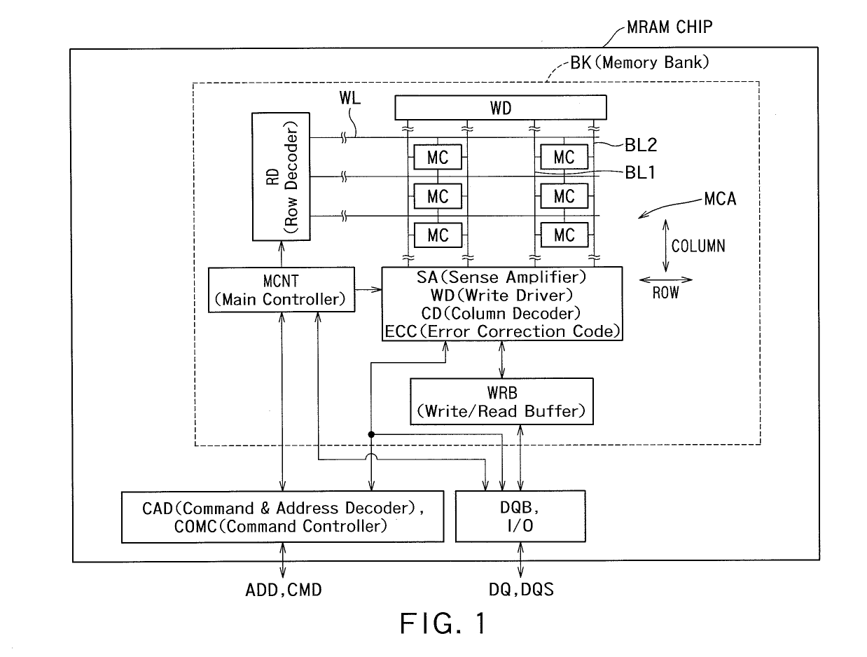

FIG. 1 is a block diagram showing an example of a configuration of an MRAM chip according to a first embodiment. The MRAM chip according to the first embodiment includes a memory bank BK, a command and address decoder CAD, a command controller COMC, a data buffer DQB, and an input/output unit I/O.

For example, the memory bank BK includes a memory cell array MCA that includes a plurality of memory cells MC arranged two-dimensionally in a matrix. Each memory cell MC is connected to a pair of bit lines (bit lines BL1 and BL2 shown in FIG. 1, for example) and to one word line WL. That is, one end of each memory cell MC is connected to one bit line BL1 of the paired bit lines BL1 and BL2 and the other end of the memory cell MC is connected to the other bit line BL2 thereof. The paired bit lines BL1 and BL2 extend in a column direction. The word lines WL extend in a row direction orthogonal to the column direction.

The memory bank BK also includes a sense amplifier SA, a write driver WD, a column decoder CD, a row decoder RD, an error correction code unit ECC, a main controller MCNT, a write/read page buffer WRB (hereinafter, also simply “page buffer WRB”).

For example, the sense amplifier SA is connected to the memory cells MC via the bit line BL1 and functions to detect data stored in the memory cells MC. At this time, the bit line BL2 is connected to a reference voltage (a ground) via the write driver WD. The write driver WD is connected to the memory cells MC via, for example, the bit lines BL1 and BL2 and functions to write data to the memory cells MC. The error correction code unit ECC generates parity based on write data and corrects an error in the data read from the memory cell array MCA using the parity. Furthermore, the error correction code unit ECC according to the first embodiment outputs an enable signal EN serving as an error notification signal when the error in the read data exceeds a correcting capability of the error correction code unit ECC. The enable signal EN is described later.

The command and address decoder CAD receives and decodes commands, addresses, and clocks that determine operations of the memory bank BK. For example, the command and address decoder CAD receives a bank address, a column address, and a row address as the addresses. For example, the command and address decoder CAD receives an active command ACR, a write command MRW, a read command MRR, and a reset command RST as the commands. The memory bank BK can perform various operations in response to these commands.

The command controller COMC receives the commands indicating the various operations such as a read operation and a write operation (hereinafter, also “data read operation” and “data write operation”), and controls the main controller MCNT according to those commands.

The main controller MCNT controls the entirety of the memory bank BK to transfer data received from the data buffer DQB to the write driver WD so as to write the data to the memory bank BK according to the addresses or to transfer data read from the memory bank BK according to the addresses to the data buffer DQB.

The column decoder CD is configured to select the paired bit lines in a certain column according to the column address. The row decoder RD selects one word line WL according to the row address.

The page buffer WRB temporarily stores the write data input via the input/output unit I/O and the data buffer DQB or temporarily stores the read data from the memory cells MC.

The data buffer DQB temporarily holds the read data or the write data so as to output the read data to outside via the input/output unit I/O or to transfer the write data fetched from outside via the input/output unit I/O to the inside.

FIG. 1 shows one memory bank BK. However, a plurality of memory banks BK are normally arranged two-dimensionally in a matrix.

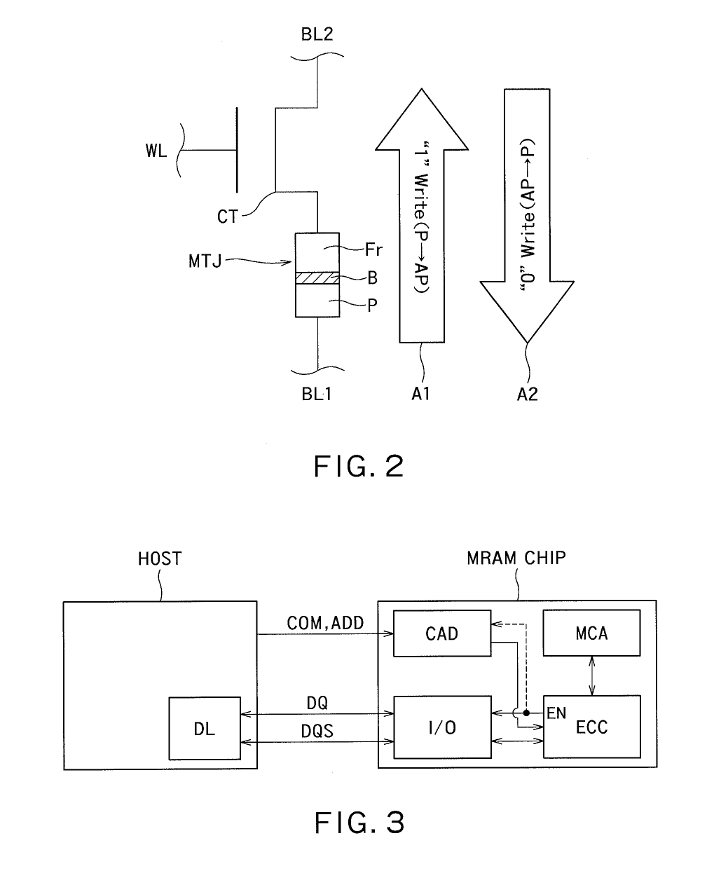

FIG. 2 is an explanatory diagram showing an example of a configuration of the single memory cell MC. Each memory cell MC includes a magnetic tunnel junction (MTJ) element and a cell transistor CT. The MTJ element and the cell transistor CT are connected in series between the bit lines BL1 and BL2. In the memory cell MC, the cell transistor CT is arranged on the side of the bit line BL2 and the MTJ element is arranged on the side of the bit line BL1. A gate of the cell transistor CT is connected to one word line WL.

The MTJ element using a TMR (tunneling magnetoresistive) effect has a stacked structure constituted by two ferromagnetic layers and a nonmagnetic layer (an insulating thin film) sandwiched between the ferromagnetic layers, and stores digital data by a change in a magnetic resistance resulting from spin-polarized tunneling. The MTJ element can be set into either a low resistance state or a high resistance state depending on magnetization orientations of the two ferromagnetic layers. For example, when it is defined that the low resistance state indicates data “0” and that the high resistance state indicates data “1”, one-bit data can be recorded in the MTJ element. Needless to mention, it can be defined that the low resistance state indicates the data “1” and that the high resistance state indicates the data “0”. For example, the MTJ element is configured so that a pinned layer P, a tunnel barrier layer B, and a recording layer Fr are sequentially stacked as shown in FIG. 3. The pinned layer P and the recording layer Fr are made of a ferromagnetic body whereas the tunnel barrier layer B is made of an insulating film. The pinned layer P is a layer having a fixed magnetization direction, the recording layer Fr is a layer having a variable magnetization direction, and data is recorded in the MTJ element depending on the magnetization direction of the recording layer Fr.

At the time of the write operation, when a current equal to or higher than an inversion threshold current flows in an arrow A1 direction, then the magnetization direction of the recording layer Fr is anti-parallel to that of the pinned layer P, and the MTJ element is set into the high resistance state (the data “1”). At the time of the write operation, when the current equal to or higher than the inversion threshold current flows in an arrow A2 direction, then the magnetization direction of the pinned layer P is parallel to that of the recording layer Fr, and the MTJ element is set into the low resistance state (the data “0”). In this way, different data can be written to the MTJ element depending on the direction of the current.

FIG. 3 is a schematic diagram showing an example of a memory system constituted by the MRAM chip and a host controller HOST according to the first embodiment. The MRAM chip includes the memory cell array MCA, the command controller COMC, the input/output unit I/O, and the error correction code unit ECC. The error correction code unit ECC can be incorporated in the main controller MCNT shown in FIG. 1.

The error correction code unit ECC generates the parity based on the write data and corrects an error in the read data from the memory cell array MCA using the parity. Furthermore, the error correction code unit ECC according to the first embodiment outputs the enable signal EN serving as the error notification signal when the error in the read data exceeds the correcting capability of the error correction code unit ECC. A one-bit signal can be used as the enable signal EN. For example, when the number of error bits of certain read data does not exceed the number of correctable bits by the error correction code unit ECC, the error correction code unit ECC activates the enable signal EN to logical high. When the number of error bits of the read data exceeds the number of correctable bits by the error correction code unit ECC, the error correction code unit ECC deactivates the enable signal EN to logical low.

By activating the enable signal EN to logical high, the input/output unit I/O enables pulses of a data strobe DQS to be output. The host controller HOST can receive the read data from the MRAM chip by receiving the pulses of the data strobe DQS. On the other hand, when the enable signal EN is logical low, the input/output unit I/O fixes the data strobe DQS to either logical high or logical low. In other words, by deactivating the enable signal EN to logical low, the input/output unit I/O disables the pulses of the data strobe DQS. The host controller HOST is thereby unable to receive the read data from the MRAM chip. In this way, the enable signal EN is transmitted to the input/output unit I/O and used to fix logic of the data strobe DQS output from the input/output unit I/O. Operations of the enable signal EN, the host controller HOST, and the MRAM chip are described later in detail.

The host controller HOST is a controller that can control a plurality of MRAM chips. The host controller HOST transmits commands COM and addresses ADD to the command and address decoder CAD of each MRAM chip. Furthermore, the host controller HOST includes a data latch circuit DL, and can store the read data from the input/output unit I/O of each MRAM chip or can store the write data to be transmitted to the MRAM chip in the data latch circuit DL. The host controller HOST can output the read data stored in the data latch circuit DL to outside of the memory package, and can receive the write data from outside of the memory package and store the write data in the data latch circuit DL.

The data strobe DQS is a reference signal that determines an output timing of the read data to be transmitted from each MRAM chip to the host controller HOST. The data strobe DQS is also a reference signal that determines an input timing of the write data to be transmitted from the host controller HOST to each MRAM chip. For example, when one MRAM chip outputs the read data as well as the data strobe DQS, the host controller HOST receives the read data using a rise or fall timing of the data strobe DQS. Data DQ shown in FIG. 3 denotes the read data or the write data.

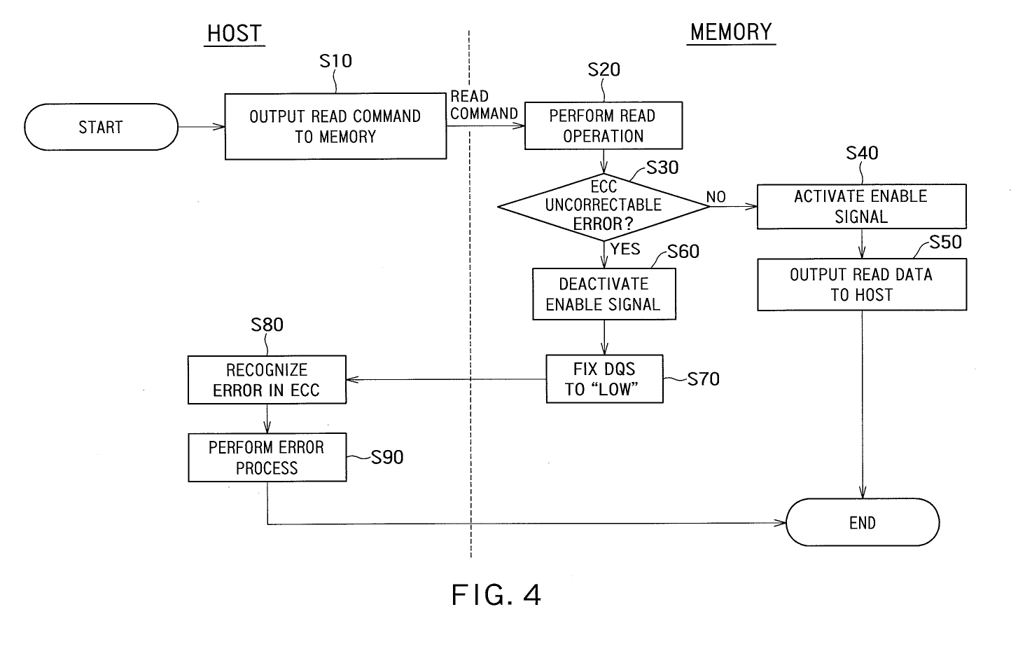

FIG. 4 is a flowchart showing an example of the data read operation performed by the MRAM chip and the host controller HOST according to the first embodiment. First, the host controller HOST outputs a read command to the MRAM chip (S10). The MRAM chip performs the read operation in response to the read command (S20). More specifically, the command and address decoder CAD shown in FIG. 1 receives a read target bank address, a read target column address, a read target row address, and the like, and decodes these addresses. The main controller MCNT controls the sense amplifier SA or the like according to the addresses decoded by the command and address decoder CAD to read data DQ from the memory cell array MCA. The read data DQ is stored in the page buffer WRB.

The error correction code unit ECC shown in FIG. 3 executes error correction to the read data DQ and then store the read data DQ in the page buffer WRB. If the number of error bits of the read data DQ does not exceed an error-correctable number of bits (that is, if the read data DQ has no error or the error bits can be correctable by the error correction code unit ECC) (NO at S30), the error correction code unit ECC keeps activating the enable signal EN (to logical high, for example) (S40). The error-correctable number of bits is the number of error bits which can be correctable by the error correction code unit ECC. At this time, the activated enable signal EN allows the input/output unit I/O to output the data DQ and the data strobe DQS. After error correction, the input/output unit I/O outputs the read data DQ and the data strobe DQS to the host controller HOST (S50).

On the other hand, if the number of error bits of the read data DQ exceeds an error-correctable number of bits (that is, if the error bits cannot be corrected by the error correction code unit ECC) (YES at S30), the error correction code unit ECC deactivates the enable signal EN (to logical low, for example) (S60). The deactivated enable signal EN have the input/output unit I/O to fix the data strobe DQS to an inactive state (logical low, for example) (S70). When the data strobe DQS is fixed to the inactive state, the host controller HOST is unable to sample the read data DQ output from the input/output unit I/O without pulses of the data strobe DQS.

Normally, the data strobe DQS and the data DQ are transmitted to the host controller HOST from the MRAM chip at the specified timing. Therefore, when any pulses of the data strobe DQS are not input to the host controller HOST for a predetermined period after specified read latency, the host controller HOST can recognize this abnormality as an error. Therefore, in the first embodiment, by fixing the data strobe DQS to the inactive state, the error is informed to the host controller HOST (S80).

When recognizing the error, the host controller HOST performs an error process (S90). For example, an error process is to freeze the operations of the host controller HOST and the MRAM chip as the error process. Alternatively, the host controller HOST can output an error signal to outside of the memory package. When one of user interface is a display, the host controller HOST can display the error on a display to inform the error to a user. Thereafter, the MRAM chip can be used for an error analysis.

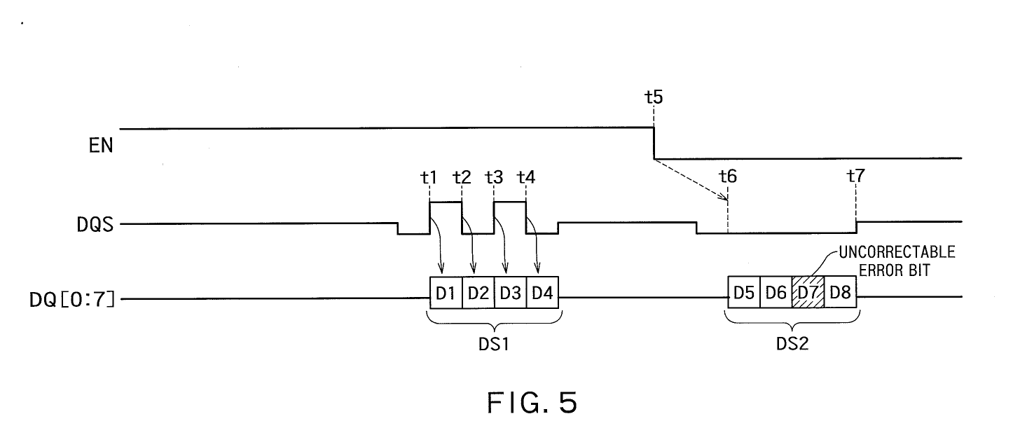

FIG. 5 is a timing chart showing an example of operations of the enable signal EN, the data strobe DQS, and the read data DQ. For example, the input/output unit I/O transmits four-byte data to the host controller HOST. In FIG. 5 four-byte (DS1 or DS2) is the unit of one dataset (DS1 or DS2). For example, the data strobe DQS is assigned to every eight input/output units I/O. That is, eight data DQ and one data strobe DQS are input to or output together from the input/output units I/O. The error correction code unit ECC executes the error correction to eight-bit data output simultaneously from these eight input/output units I/O. Therefore, while FIG. 5 shows each of data D1 to D8 as one frame, each of the data D1 to D8 shows eight-bit data. For example, the error correction code unit ECC corrects an error in the eight-bit data D1, and then transfers the eight-bit data D1 to the host controller HOST. For example, the error correction code unit ECC corrects an error in each of the eight-bit data D2 to D8, and transfers each of the eight-bit data D2 to D8 to the host controller HOST. The number of bits of the dataset DS1 or DS2 and the number of input/output units I/O sharing the data strobe DQS are not limited to specific numbers.

The read data DQ is transferred with the rise timing and the fall timing of the data strobe DQS. For example, the data D1 is output at a time t1 that is the rise timing of the data strobe DQS, the data D2 is output at a time t2 that is the fall timing of the data strobe DQS, the data D3 is output at a time t3 that is the rise timing of the data strobe DQS, and the data D4 is output at a time t4 that is the fall timing of the data strobe DQS. In this way, the read data D1 to D4 in the dataset DS1 are consecutively transferred to the host controller HOST to correspond to the timing of the time t1, the timing of the time t2, the timing of the time t3, and the timing of the time t4, respectively.

In the example of FIG. 5, it is assumed that the read data D1 to D4 are not error bits. Alternatively, it is assumed that the error correction code unit ECC is able to correct the error in the read data D1 to D4. Therefore, the enable signal EN is activated to logical high.

As for the next dataset DS2, it is assumed that the read data D7 is an error bit and that the error correction code unit ECC is unable to correct the errors in the read data D7. In this case, the error correction code unit ECC deactivates the enable signal EN to logical low at a time (t5) at which it is determined that the error correction code unit ECC is unable to correct the error in the data D7. Therefore, when the data strobe DQS and the dataset DS2 (D5 to D8) are transferred from the input/output units I/O to the host controller HOST, the enable signal EN is deactivated to logical low. Because the enable signal EN is inactive, the input/output units I/O fix the data strobe DQS to the inactive state (logical low) after a time t6. Therefore, after the time t6, the host controller HOST can recognize the error. Although the data strobe DQS falls to logical low just before the time t6, this operation is a normal operation as shown before the time t1. Accordingly, before the time t6, the host controller HOST is unable to recognize the error.

When the data strobe DQS is fixed to logical low, the dataset DS2 cannot be sampled by the host controller HOST. Since the rise timing of the data strobe DQS is not available at the specified read latency as shown in the time t6, the host controller HOST can recognize the occurrence of the error (timeout) and perform the error process (Step S90 shown in FIG. 4).

According to the first embodiment, when the uncorrectable error occur, the input/output units I/O fix the data strobe DQS to either logical high or logical low during outputting the read data D5 to D8. The host controller HOST can thereby recognize the error without receiving the dataset DS2 including the error bits. After the host controller HOST recognizes the error, the host controller HOST and the MRAM chip stop the read operation and perform the error process.

At this time, when the host controller HOST receives the dataset DS2 including the uncorrectable error bits, the host controller HOST spreads the error data. For example, when the data stored in the MRAM chip is program data, an electronic device executing the error dataset DS2 is likely to malfunction or out of control.

In contrast, according to the first embodiment, when the error correction code unit ECC is unable to correct the error bit, the host controller HOST and the MRAM chip stop the read operation. Accordingly, the dataset DS2 including the error bits is not output from the memory. Therefore, it is possible to suppress the electronic device from malfunctioning and out of control state.

In the first embodiment, the enable signal EN can be transmitted not only to the input/output units I/O but also to the command and address decoder CAD as indicated by a broken line in FIG. 3. In this case, when the enable signal EN is deactivated, the command and address decoder CAD stops operating. The command and address decoder CAD can be configured to ignore receive commands and addresses other than a specific command in response to the deactivated EN. That is, the MRAM chip cannot be accessed. For example, the specific command is a command necessary for the analysis or a command to cancel access limitation. The specific command can be issue to add a flag bit indicating that the command is the specific to a normal command. Even if the access to the MRAM chip is limited by restricting the operation of the command and address decoder CAD as described above, effects of the first embodiment are not lost.

Furthermore, when the enable signal EN is deactivated, the input/output units I/O can fix the data strobe DQS to logical high. Even if the data strobe DQS is fixed to logical high, both rising and falling edge of the data strobe DQS are not output to the host controller HOST. Therefore, the host controller HOST can recognize the error.

In the first embodiment, the error correction code unit ECC executes the error correction to each of the eight-bit data (D1 to D8). However, the error correction code unit ECC can execute the error correction to each of the datasets (DS1 or DS2) output from each input/output unit I/O. In this case, the error correction code unit ECC executes the error correction to the four-sequential data on each input/output units I/O. Also the error correction code unit ECC can execute the error correction to each of the datasets (DS1 or DS2) output from the eight input/output units I/O. That is, in this case, the error correction code unit ECC can execute the error correction to 8 I/O×4 sequential bit data. Regardless the unit of ECC application, the MRAM chip can stop reading the dataset (DS2) including the uncorrectable error.

### (Modification)

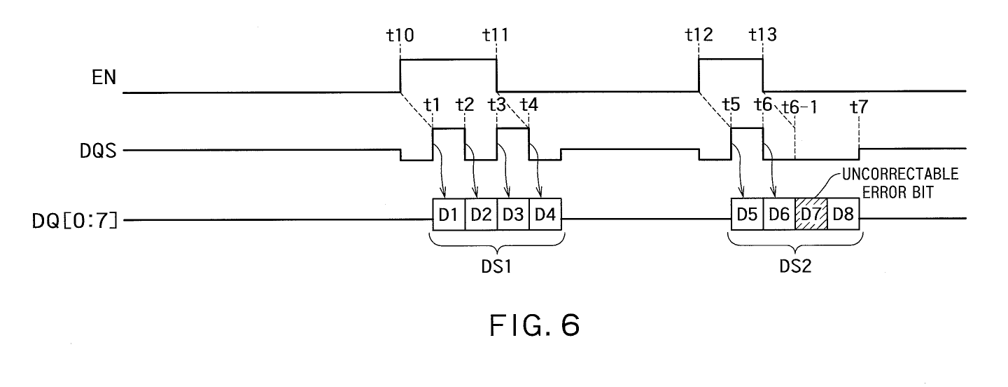

FIG. 6 is a timing chart showing an example of operations of the enable signal EN, the data strobe DQS, and the read data DQ according to a modification of the first embodiment. In the modification, the error correction code unit ECC activates the enable signal EN to logical high in periods (from a time t10 to a time t11 and from a time t12 to a time t13) in order to allow outputting the pulses of the data strobe DQS, and deactivates the enable signal EN to logical low in the other periods.

Therefore, before the time t10, the enable signal EN is deactivated to logical low. In the period from the time t10 to the time t11, the enable signal EN is activated to logical high. From the time t1 to the time t4 corresponding to the period from the time t10 to the time t11, the input/output unit I/O thereby enables to output the pulses of the data strobe DQS. Therefore, similarly to the first embodiment, the dataset DS1 is transferred from the input/output unit I/O to the host controller HOST.

Next, in a period from the time t11 to the time t12, the enable signal EN is deactivated to logical low. The data DQ is not output because this period is a period between output of the dataset DS1 and output of the dataset DS2.

In the period from the time t12 to the time t13, the enable signal EN is activated to logical high. In a period from the time t5 to a time t6-1 corresponding to the period from the time t12 to the time t13, the input/output unit I/O enables to output the pulses of the data strobe DQS. Therefore, the data D5 and the data D6 in the dataset DS2 and a pulse of DQS are normally transferred from the input/output unit I/O to the host controller HOST. However, after the time t13, the enable signal EN is deactivated to logical low. After the time t6-1 corresponding to the time t13, the data strobe DQS is thereby fixed to logical low and the pulses of the data strobe DQS are not output. Accordingly, the host controller HOST is unable to sample the data D7 and D8 in the dataset DS2 without the pulse of the data strobe DQS even if the data D7 and D8 are transferred from the input/output unit I/O to the host controller HOST.

In this way, the MRAM chip according to the modification enables the pulses of data strobe DQS correspond to the data D1 to D6 just before the uncorrectable data D7 to be transferred normally and does not transfer the pulse of read strobe DQS after the uncorrectable data D7. That is, the enable signal EN does not disable the transfer of the entire dataset DS2 including the uncorrectable data D7 but transfers the effective bits (D5 and D6) in the dataset DS2 to the host controller HOST and disables the transfer of the bits (D7 and D8) including the uncorrectable data.

The MRAM chip according to the modification can transfer the effective bits (D1 to D6) just before the uncorrectable bit (D7) in the dataset DS2 to the host controller HOST. Therefore, according to the modification, it is possible to transfer much effective data to the host controller HOST as compared with the first embodiment.

In the modification, similarly to the first embodiment, the logic (level) of the data strobe DQS is fixed at the output timing (t6-1) of the data D7 so as to prevent the uncorrectable data D7 from being sampled by the host controller HOST. Therefore, the modification can achieve the effects identical to those of the first embodiment.

### Second Embodiment

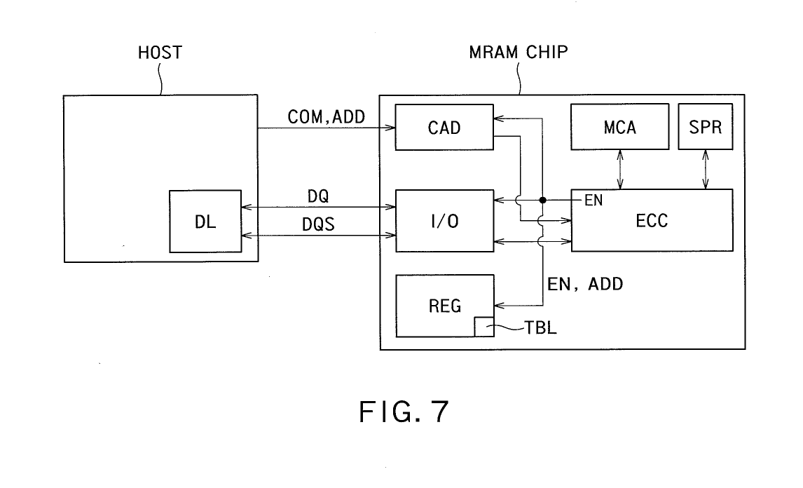

FIG. 7 is a schematic diagram showing an example of a memory system constituted by an MRAM chip and a host controller according to a second embodiment. The MRAM chip has an analysis register REG, a spare memory region SPR, and a table storage region TBL. Other configurations of the second embodiment can be identical to that of the first embodiment.

The analysis register REG stores an address ADD (hereinafter, also “error address”) of the uncorrectable read data when uncorrectable error occurs. The analysis register REG can also store history data such as accessed addresses, data, and commands before and after the occurrence of the uncorrectable error. The history data stored in the analysis register REG is used for an error analysis of the MRAM chip.

The spare memory region SPR is used as a spare of error bits (the memory cells MC storing the read data) of the memory cell array MCA when the uncorrectable error occurs. The spare memory region SPR stores backup data that replaces the uncorrectable read data. The backup data is correct data corresponding to the read data and obtained from the host controller HOST based on the address stored in the analysis register REG. Units per usage in the spare memory region SPR are not limited to specific ones. Therefore, the table storage region TBL of the spare memory region SPR stores an address conversion table. When the uncorrectable error data are replaced with spare memory region SPR stores the backup data, it is necessary to update the address conversion table to change a physical address including uncorrectable error to a physical address of the spare memory region SPR. The address conversion table is stored in the table storage region TBL. The address conversion table can be managed by the host controller HOST.

The analysis register REG, the spare memory region SPR, and the table storage region TBL can be registers or dedicated memory region on the MRAM chip separately from the memory cell array MCA. Alternatively, the analysis register REG, the spare memory region SPR, and the table storage region TBL can be a part of a memory region in the memory cell array MCA. When a plurality of spare memory regions SPR are provided, unused spare memory regions SPR among all the spare memory regions SPR can be stored in the analysis register REG and can be used when the repair is required.

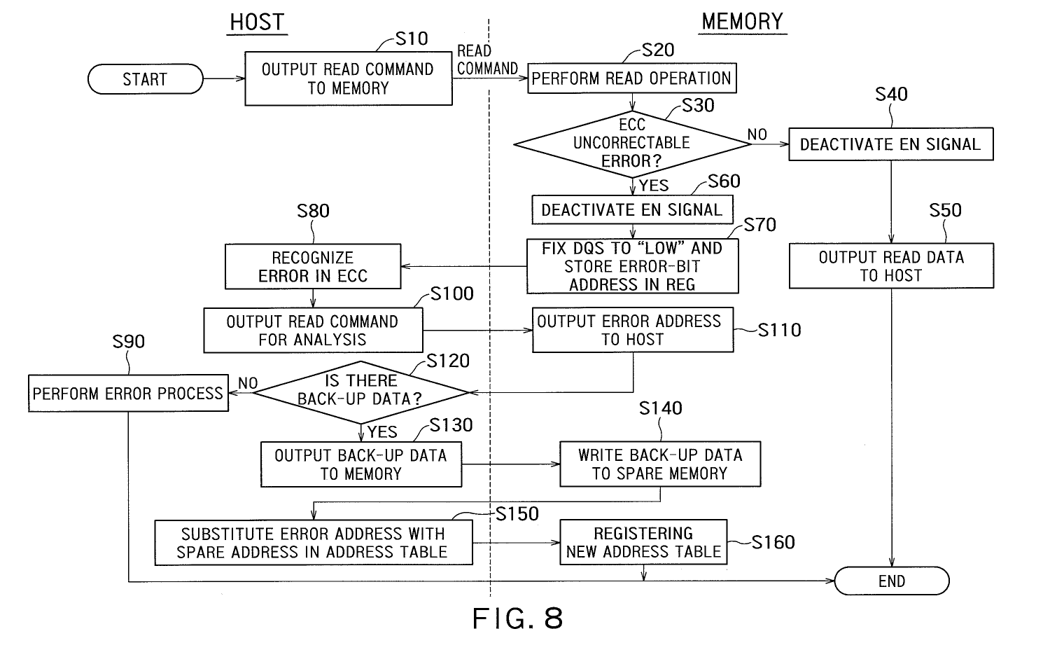

FIG. 8 is a flowchart showing an example of the data read operation performed by the MRAM chip and the host controller HOST according to the second embodiment. Operations at Steps S10 to S80 can be identical to those at Steps S10 to S80 shown in FIG. 4. However, at Step S70, the error correction code unit ECC fixes the logic of the data strobe DQS and the address ADD of the uncorrectable read data is stored in the analysis register REG. At this time, as described above, not only the address ADD of the read data but also information such as the read data and the commands can be stored in the analysis register REG for the analysis. Furthermore, the history data such as the accessed addresses, data, and commands before and after the occurrence of the error can be stored in the analysis register REG.

When the host controller HOST recognizes the error determined by the error correction code unit ECC (S80), the host controller HOST outputs a read command to the MRAM chip so as to obtain the error address ADD of the read data stored in the analysis register REG (S100). When the MRAM chip does not permit an access to the MRAM by commands other than a specific command, the host controller HOST unlocks the access limitation on the MRAM chip using a specific command or transmits the specific read command by adding a flag bit to the read command.

When the command and address decoder CAD receives this read command for the analysis, the error address ADD stored in the analysis register REG is output to the host controller HOST (110).

In response to the error address ADD, the host controller HOST confirms whether there is backup data corresponding to the error address ADD (S120). For example, when the MRAM chip according to the second embodiment functions as a working memory and stores program data, another storage device such as an HDD (Hard Disc Drive), an SSD (Solid State Drive) or a memory card often stores the same program data. Therefore, the host controller HOST can obtain the correct data corresponding to the read data from another storage device as the backup data.

When there is the backup data as described above (YES at S120), the host controller HOST outputs the backup data to the MRAM chip (S130). At this time, the host controller HOST can transmit a write command as a specific command by adding a flag bit to the write command. The host controller HOST transmits the write command together with an address in the spare memory region SPR to the MRAM chip.

The MRAM chip stores the backup data in the spare memory region SPR (S140). That is, the uncorrectable read data is replaced with the correct data.

The host controller HOST updates the address conversion table to change the physical address of the error address ADD to the physical address of the spare memory region SPR in which the backup data is stored (S150). Updating the address conversion table allows the MRAM chip to access the spare memory region SPR at a next time the same logical address is accessed.

Next, the updated address conversion table is transmitted to the MRAM chip and stored in the table storage region TBL (S160). The MRAM chip thereby turns into an accessible state. That is, the host controller HOST can issue the specific command to resume the normal operation of the enable signal EN for the MRAM chip.

When the same address is to be read after resuming normal operation, the MRAM chip accesses the spare memory region SPR and reads the backup data as described above. The MRAM chip can output correct data because the backup data is in a no-error state or an error-correctable state.

When there is no backup data (NO at S120), the host controller HOST performs the error process (S90). The error process at Step S90 can be identical to that in the first embodiment.

Other operations of the second embodiment can be identical to corresponding ones of the first embodiment. Therefore, the second embodiment can achieve effects identical to those of the first embodiment.

Furthermore, in the memory system according to the second embodiment, the host controller HOST transmits the backup data of the uncorrectable read data to the MRAM chip based on the error address ADD in the analysis register REG. The MRAM chip stores the backup data in the spare memory region SPR, and outputs the backup data to replace with the uncorrectable read data. With this configuration, when an uncorrectable error occurs, the MRAM chip can not only stop read operation without error data output but also subsequently resume the read operation and the write operation. That is, the MRAM chip can stop the read operation and then return to an accessible state when the uncorrectable error occurs.

### Third Embodiment

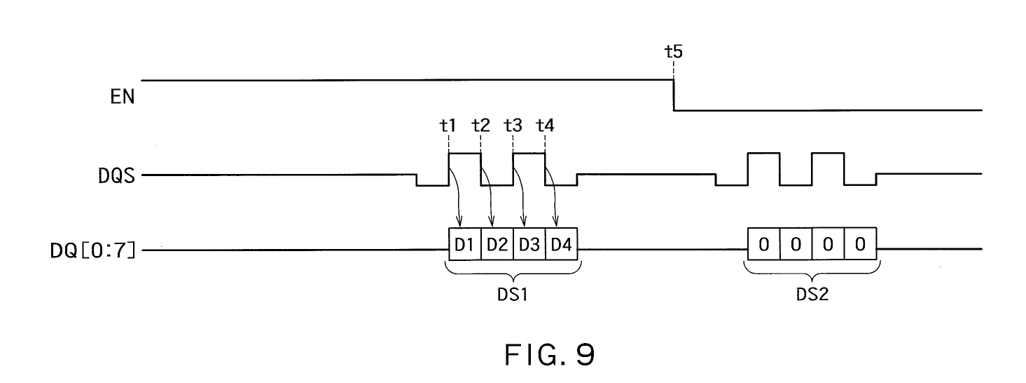

FIG. 9 is a timing chart showing an example of operations of the enable signal EN, the data strobe DQS, and the read data DQ according to a third embodiment. Configurations of the MRAM chip and the host controller can be identical to those of the first or second embodiment.

In the third embodiment, when the read data is uncorrectable by the error correction code unit ECC, the input/output unit I/O outputs a data pattern (hereinafter, also “error pattern”) indicating the occurrence of an error instead of the read data. Therefore, the enable signal EN is kept activated (to logical high) and the data strobe DQS is not disabled. While the error pattern is not limited to a specific type, a dataset “0000” or “1111”, for example, can be used as the error pattern. In FIG. 9, the dataset “0000” can be an error pattern as one of examples. Normally, pieces of data stored in a memory are allocated so that each of logic is equally present by randomization. It is assumed that this randomization is performed excluding the error pattern (“0000”, for example). This configuration makes it possible to prevent normal read data from being made identical to the error pattern.

In the third embodiment, the enable signal EN serving as the error notification signal is not for enabling or disabling the data strobe DQS but for outputting the error pattern from the input/output unit I/O. For example, when the read data is in an error-correctable state and the enable signal EN is activated to logical high (before the time t5), the input/output unit I/O enables the read data to be output as it is. On the other hand, when the read data is in an error-uncorrectable state and the enable signal EN is deactivated to logical low (at and after the time t5), the input/output unit I/O outputs the error pattern “0000”. The host controller HOST can thereby recognize the occurrence of an error in the MRAM chip.

Other operations of the third embodiment can be identical to corresponding ones of the first or second embodiment. Therefore, the third embodiment can achieve effects identical to those of the first or second embodiment.

Furthermore, the MRAM chip can output the enable signal EN to the host controller HOST as it is. The host controller HOST can thereby recognize the occurrence of an error based on the enable signal EN.

A memory cell array formation may be disclosed in U.S. patent application Ser. No. 12/407,403 filed on Mar. 19, 2009. U.S. patent application Ser. No. 12/407,403, the entire contents of which are incorporated by reference herein.

Furthermore, a memory cell array formation may be disclosed in U.S. patent application Ser. No. 12/406,524 filed on Mar. 18, 2009. U.S. patent application Ser. No. 12/406,524, the entire contents of which are incorporated by reference herein.

Furthermore, a memory cell array formation may be disclosed in U.S. patent application Ser. No. 12/679,991 filed on Mar. 25, 2010. U.S. patent application Ser. No. 12/679,991, the entire contents of which are incorporated by reference herein.

Furthermore, a memory cell array formation may be disclosed in U.S. patent application Ser. No. 12/532,030 filed on Mar. 23, 2009. U.S. patent application Ser. No. 12/532,030, the entire contents of which are incorporated by reference herein.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a memory cell array including a plurality of memory cells;
an output part configured to output data based on a strobe signal; and
an error correction part configured to correct an error in first data read from the memory cell array, wherein
the output part fixes level of the strobe signal when outputting the first data, if number of error bits of the first data exceeds a first number, the error correction part being capable of correcting error of the first number in the first data.

2. The device of claim 1, wherein
the error correction part outputs a first control signal to the output part, if the number of error bits of the first data exceeds the first number, and
the output part fixes the level of the strobe signal when the output part receives the first control signal.

3. The device of claim 1, wherein the level of the strobe signal is fixed for a first period.

4. The device of claim 3, wherein the first period is a period in which an external controller determines occurrence of the error.

5. The device of claim 1, further comprising a first register configured to store an address of the first data.

6. The device of claim 1, wherein the output part fixes the level of the strobe signal determining a data output timing to one of two types of level when outputting the first read data, if the number of error bits of the first data exceeds the first number.

7. A semiconductor storage device comprising:
a memory cell array including a plurality of memory cells;
an output part configured to output data based on a strobe signal; and
an error correction part configured to correct an error in first data read from the memory cell array, wherein
the output part outputs a data pattern indicating occurrence of the error when outputting the first data, if number of error bits of the first data exceeds a first number, the error correction part being capable of correcting error of the first number in the first data.

8. The device of claim 7, wherein
the error correction part outputs a first control signal to the output part, if the number of error bits of the first data exceeds the first number, and
the output part outputs the data pattern when the output part receives the first control signal.

9. The device of claim 7, further comprising a first register configured to store an address of the first data.

10. The device of claim 7, wherein the output part outputs the data pattern indicating the occurrence of the error in place of the first data, if the first data includes errors exceeding the first number.

11. A memory system comprising: a semiconductor storage device and a host controller,
wherein the semiconductor storage device comprises: a memory cell array including a plurality of memory cells; an output part configured to output data based on a strobe signal;
and an error correction part configured to correct an error in first data read from the memory cell array, wherein the output part fixes level of the strobe signal when outputting the first data, if number of error bits of the first data exceeds a first number, the error correction part being capable of correcting error of the first number in the first data,
wherein the host controller is configured to transmit backup data of the first data to the semiconductor storage device by using an address of the first data.

12. The system of claim 11, further comprising an analysis register configured to store the address of the first data, if the number of error bits of the first data exceeds the number of correctable bits by the error correction part, wherein
the host controller transmits the backup data of the first data to the semiconductor storage device by using the address of the first data in the analysis register.

13. The system of claim 11, further comprising:
a spare memory region configured to store the backup data; and
a table storage region configured to store an address conversion table, the address of the first data being changed to an address of the backup data in the spare memory region in the address conversion table.

14. The system of claim 13, wherein the semiconductor storage device reads and outputs the backup data stored in the spare memory region according to the address conversion table stored in the table storage region, if the first data is accessed.
